(19) United States
(12) Patent Application Publication
(10) Pub. No.: US 2007/0123022 A1
(43) Pub. Date: May 31, 2007

(54) Semiconductor device manufacturing method

(75) Inventors: Takeshi Wakabayashi, Sayama-shi (JP); Ichiro Mihara, Tachikawa-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: CASIO COMPUTER CO., LTD., Tokyo (JP)

(21) Appl. No.: 11/604,028

(22) Filed: Nov. 22, 2006

(30) Foreign Application Priority Data
Nov. 30, 2005 (JP) 2005-345613

(51) Int. Cl. H01L 21/44

(52) U.S. Cl. 438/613

(57) ABSTRACT

There is prepared a semiconductor construction in which a plurality of columnar electrodes are provided on an upper side of a semiconductor substrate and in which a sealing film is provided on the semiconductor substrate to cover outer peripheral surfaces of the columnar electrodes. Upper sides of the columnar electrodes are removed to form openings in the sealing film on the supper sides of the columnar electrodes. Adhesive coatings are formed on upper surfaces of the columnar electrodes in the openings of the sealing film, Solder balls are provided on upper surfaces of the adhesive coatings. Finally, the solder balls are deformed by a heat treatment to form solder bumps in and above the openings of the sealing film so that the solder bumps are connected to the upper surfaces of the columnar electrodes. Thus, a semiconductor device is manufactured.

### CROSS-REFERENCE TO RELATED APPLICATIONS

This application is based upon and claims the benefit of priority from prior Japanese Patent Application No. 2005-345613, field Nov. 30, 2005, the entire contents of which are incorporated herein by reference.

### BACKGROUND OF THE INVENTION

1. Field of the Invention

This invention relates to a semiconductor device manufacturing method.

2. Description of the Related Art

For example, there is a conventional method of forming solder in a connection pad portion of a wiring line of a circuit substrate. This method comprises: forming an adhesive coating on the connection pad portion of the wiring line formed on the substrate; sprinkling solder powder on the substrate to deposit the solder powder only onto the adhesive coating; melting the solder powder by a heat treatment; and forming a solder layer on the connection pad portion of the wiring line (e.g., refer to Jpn. Pat. Appln. KOKAI Publication No. 6-152120).

In the conventional solder forming method described above, the solder powder is sprinkled on the substrate to deposit the solder powder only onto the adhesive coating formed on the connection pad portion of the wiring line. It is therefore impossible to deposit the solder powder onto the adhesive coating in a bulging state, so that the thickness of the solder layer formed on the connection pad portion of the wiring line is relatively small.

There is known a conventional semiconductor device called a chip size package (CSP), wherein a wiring line is provided on an upper surface of an insulating film provided on a silicon substrate, a columnar electrode is provided on an upper surface of a connection pad portion of the wiring line, and a sealing film is provided on the upper surface of the insulating film including the wiring line so that this sealing film covers an outer peripheral surface of the columnar electrode.

In such a semiconductor device, when an external connection terminal made of solder is formed on the columnar electrode, the thickness of a solder layer formed on the columnar electrode is relatively small if the conventional solder forming method described above is used, so that there is a problem that such a solder forming method is unsuitable when, for example, flip chip bonding is carried out.

### BRIEF SUMMARY OF THE INVENTION

Therefore, this invention is directed to provide a semiconductor device manufacturing method in which solder balls are provided only onto columnar electrodes, and then solder bumps can be formed on the columnar electrodes by a heat treatment.

In order to achieve the foregoing object, this invention provides semiconductor device manufacturing method comprising:

preparing a semiconductor construction in which a plurality of columnar electrodes are provided on an upper side of a semiconductor substrate and in which a sealing film is provided on the semiconductor substrate to cover outer peripheral surfaces of the columnar electrodes;

removing upper sides of the columnar electrodes so as to form openings in the sealing film on the supper sides of the columnar electrodes;

forming adhesive coatings on upper surfaces of the columnar electrodes in the openings of the sealing film;

providing solder balls onto upper surfaces of the adhesive coatings; and

deforming the solder balls by a heat treatment to form solder bumps in and above the openings of the sealing film so that the solder bumps are connected to the upper surfaces of the columnar electrodes.

According to this invention, the solder balls are provided onto the upper surfaces of the adhesive coatings formed on the upper surfaces of the columnar electrodes in the openings of the sealing film, so that the solder balls are provided only onto the columnar electrodes, and then the solder bumps can be formed on the columnar electrodes by the heat treatment.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the preferred embodiments given below, serve to explain the principles of the invention.

FIG. 1 is a sectional view of one example of a semiconductor device manufactured by a manufacturing method according to one embodiment of this invention;

FIG. 2 is a sectional view of an assembly initially prepared for the manufacture of the semiconductor device shown in FIG. 1;

FIG. 3 is a sectional view in a process following FIG. 2;

FIG. 4 is a sectional view in a process following FIG. 3;

FIG. 5 is a sectional view in a process following FIG. 4;

FIG. 6 is a sectional view in a process following FIG. 5; and

FIG. 7 is a sectional view in a process following FIG. 6.

### DETAILED DESCRIPTION OF THE INVENTION

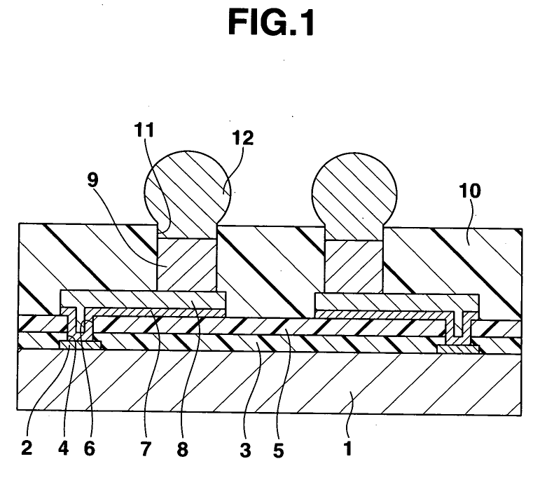

FIG. 1 shows a sectional view of one example of a semiconductor device manufactured by a manufacturing method according to one embodiment of this invention. This semiconductor device includes a silicon substrate (semiconductor substrate) 1. An integrated circuit having a predetermined function is provided on an upper surface of the silicon substrate 1. A plurality of connection pads 2 made of metal, for example, an aluminum-based metal are provided on a peripheral portion of the upper surface of the silicon substrate 1 so that these connection pads 2 are electrically connected to the integrated circuit.

An insulating film 3 made of, for example, silicon oxide is provided on the upper surfaces of the connection pads 2 except for central portions thereof and on the upper surface of the silicon substrate 1. The central portions of the connection pads 2 are exposed via openings or through holes 4 formed in the insulating film 3. A protective film 5 made of, for example, a polyimide-based resin is entirely provided on an upper surface of the insulating film 3. Openings or through holes 6 are formed in the protective film 5 in parts corresponding to the openings 4 of the insulating film 3.

A plurality of foundation metal layers 7 made of, for example, copper are provided on an upper surface of the protective film 5. A wiring line 8 made of copper is entirely provided on an entire upper surface of each of the foundation metal layers 7. One end of the wiring line 8 including the foundation metal layer 7 is electrically connected to the connection pad 2 via the openings 4 and 6 of the insulating film 3 and the protective film 5. A columnar electrode 9 made of copper is provided on an upper surface of a connection pad portion at the other end of the wiring line 8. The height of this columnar electrode is 30 to 150 μm.

A sealing film 10 made of, for example, an epoxy-based resin is provided on the upper surface of the protective film 5 and the wiring lines 8 to cover outer peripheral surfaces of the columnar electrodes 9 so that an upper surface of this sealing film 10 is higher than an upper surface of each of the columnar electrodes 9. Therefore, openings 11 are formed in the sealing film 10 above the columnar electrodes 9. Solder bumps 12 are provided in and above the openings 11 of the sealing film 10 so that these solder bumps 12 are electrically and mechanically connected to the upper surfaces of the columnar electrodes 9.

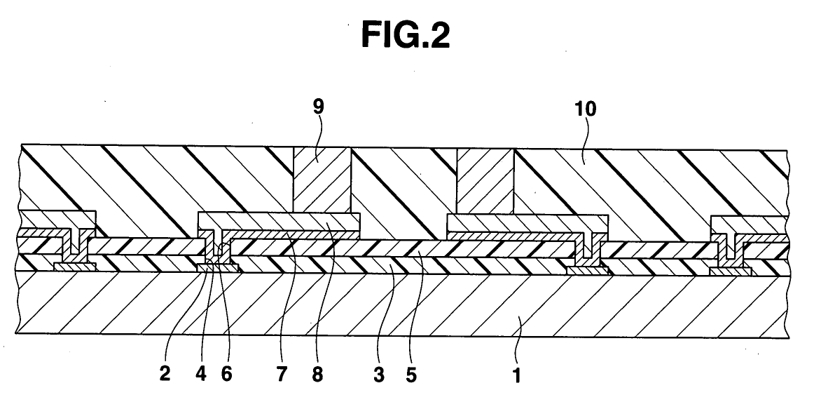

Next, one example of the method of manufacturing this semiconductor device will be described. First, as shown in FIG. 2, an assembly is prepared, wherein the connection pads 2 are formed on the upper surface of the silicon substrate 1 in a wafer state; the insulating film 3 and the protective film 5 are sequentially formed on the upper surfaces of the connection pads 2 and the silicon substrate 1; the wiring lines 8 including the foundation metal layers 7 are formed on the upper surface of the protective film 5 so that they are electrically connected to the connection pads 2 via the openings 4 and 6 of the insulating film 3 and the protective film 5; the columnar electrodes 9 are formed on the upper surface of the connection pad portion of each of the wiring lines 8; and the sealing film 10 is formed on the upper surface of the protective film 5 and the wiring lines 8 so that the upper surface of this sealing film 10 is flush with the upper surfaces of the columnar electrodes 9.

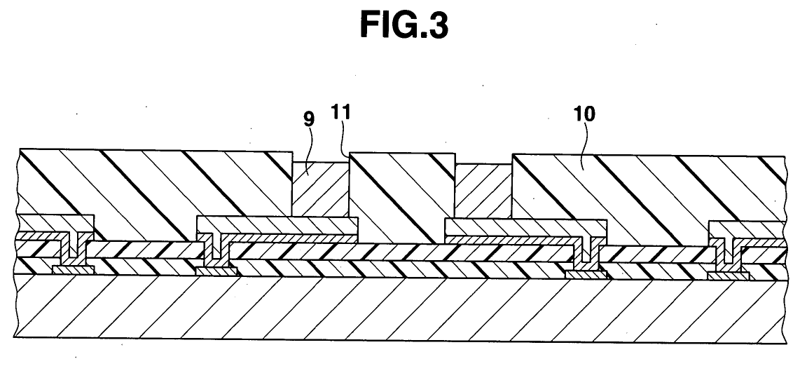

Next, as shown in FIG. 3, upper sides of the columnar electrodes 9 are slightly removed by for example etching so as to form the openings 11 in the sealing film 10 on the upper sides of the columnar electrodes 9. A method of etching at this point may be dry etching or wet etching. However, the wet etching without requiring a mask is efficient in this etching process, and a sulfuric acid-hydrogen peroxide base solution, an ammonium persulfate base solution, a cupric chloride solution or the like is used as an etching solution when the columnar electrodes 9 are made of copper.

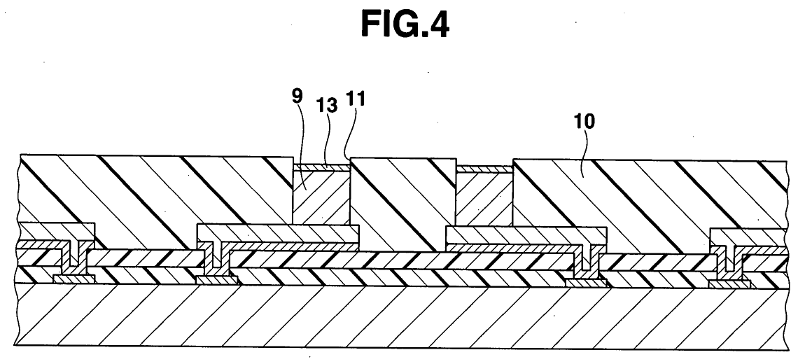

Next, as shown FIG. 4, adhesive coatings 13 are provided or formed on the upper surfaces of the columnar electrodes 9 in the openings 11 of the sealing film 10. A method of forming the adhesive coatings 13 includes, by way of example, immersing the assembly shown in FIG. 3 into an unshown imidazole-based compound solution contained in a container, such that the adhesive coatings 13 made of an imidazole-based compound are formed only on the exposed metal surfaces of the assembly shown in FIG. 3, that is, only on the upper surfaces of the columnar electrodes 9 exposed via the openings 11 of the sealing film 10. In this state, upper surfaces of the adhesive coatings 13 are somewhat lower than the upper surface of the sealing film 10.

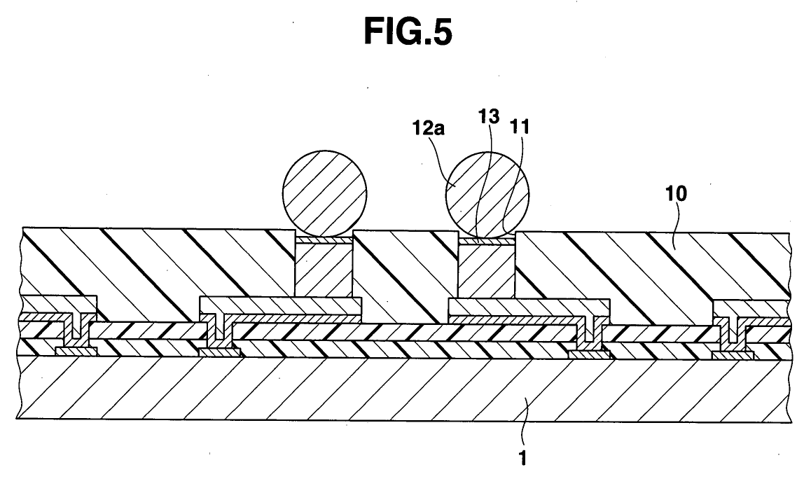

Next, as shown in FIG. 5, solder balls 12a are provided or deposited onto the upper surfaces of the adhesive coatings 13. A method of depositing the solder balls 12a includes, by way of example, amply scattering a large number of solder balls 12a on the upper surfaces of the adhesive coatings 13 exposed via the openings 11 of the sealing film 10 and on the upper surface of the sealing film 10, while the silicon substrate 1 in the wafer state is kept horizontally, and then inclining the silicon substrate 1 to some degree, such that extra solder balls other than the solder ball 12a which has entered each of the openings 11 of the sealing film 10 and deposited onto the upper surface of the adhesive coating 13 roll on the sealing film 10, fall, and are thus removed.

In this case, the upper surfaces of the adhesive coatings 13 are somewhat lower than the upper surface of the sealing film 10, and this can make it difficult for the solder ball 12a which have once entered the opening 11 of the sealing film 10 to come out. Moreover, since the diameter of the solder ball 12a is set to be somewhat larger than the diameter of the columnar electrode 9, that is, the diameter of the opening 11 of the sealing film 10, two solder balls 12a do not enter one opening 11.

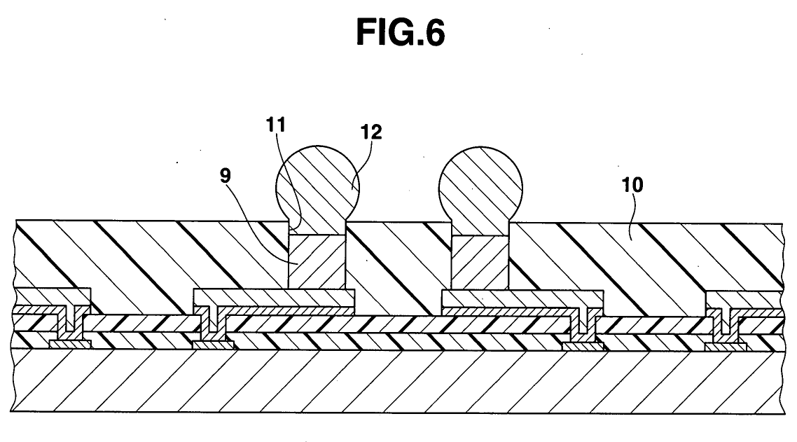

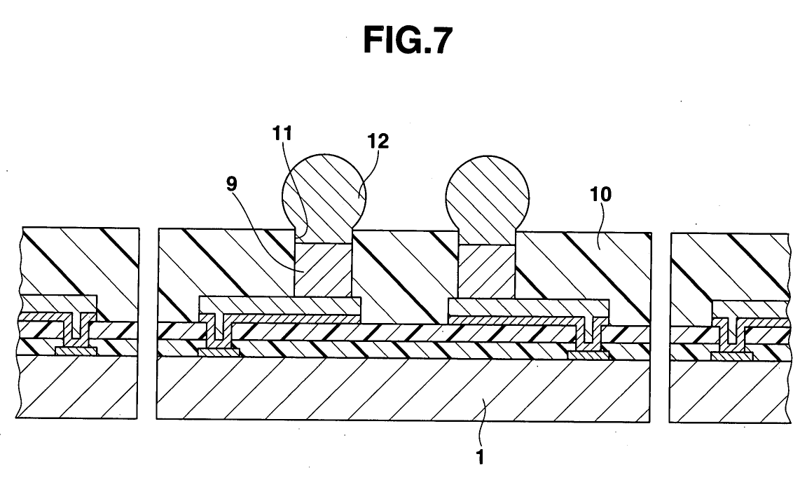

Next, a heat treatment is carried out to deform or melt the solder balls 12a and evaporate and remove the adhesive coatings 13, thereby forming the solder bumps 12 in and above the openings 11 of the sealing film 10 so that the solder bumps 12 are electrically and mechanically connected to the upper surfaces of the columnar electrodes 9, as shown in FIG. 6. Then, as shown in FIG. 7, a dicing process is carried out against the resultant assembly to obtain a plurality of semiconductor devices shown in FIG. 1.

As described above, in this semiconductor device manufacturing method, the solder balls 12a are deposited onto the upper surfaces of the adhesive coatings 13 formed on the upper surfaces of the columnar electrodes 9 in the openings 11 of the sealing film 10, so that the solder ball 12a are provided only onto each of the columnar electrodes 9, and then the solder bumps 12 can be formed on the columnar electrodes 9 by the heat treatment.

Furthermore, when the adhesive coatings 13 are formed, the assembly shown in FIG. 3 is immersed into the imidazole-based compound solution contained in the container, and the adhesive coatings 13 made of the imidazole-based compound are formed only on the upper surfaces of the columnar electrodes 9 exposed via the openings 11 of the sealing film 10. Thus, even when the arrangement pitch of the columnar electrodes 9 is small, the adhesive coatings 13 can be easily and reliably formed only on the upper surfaces of the columnar electrodes 9, and the solder balls 12a can be stably installed on the columnar electrodes 9 via the deposit of the solder balls 12a onto the adhesive coatings 13 formed only on the upper surfaces of the columnar electrodes 9.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device manufacturing method comprising:
preparing a semiconductor construction in which a plurality of columnar electrodes are provided on an upper side of a semiconductor substrate and in which a sealing film is provided on the semiconductor substrate to cover outer peripheral surfaces of the columnar electrodes;
removing upper sides of the columnar electrodes so as to form openings in the sealing film on the supper sides of the columnar electrodes;
forming adhesive coatings on upper surfaces of the columnar electrodes in the openings of the sealing film;
providing solder balls onto upper surfaces of the adhesive coatings; and
deforming the solder balls by a heat treatment to form solder bumps in and above the openings of the sealing film so that the solder bumps are connected to the upper surfaces of the columnar electrodes.

2. The manufacturing method according to claim 1, wherein the adhesive coatings are formed so that the upper surfaces thereof are lower than an upper surface of the sealing film.

3. The manufacturing method according to claim 1, wherein the adhesive coatings are formed of an imidazole-based compound.

4. The manufacturing method according to claim 1, wherein the adhesive coatings are formed by immersing the semiconductor construction into an imidazole-based compound solution.

5. The manufacturing method according to claim 1, wherein the semiconductor substrate is a semiconductor wafer, and a plurality of semiconductor devices are obtained by dicing the semiconductor wafer after the solder bumps are formed.

6. A semiconductor device manufacturing method comprising:
providing a semiconductor substrate having a plurality of connection pads on one surface thereof;
forming, on the one surface side of the semiconductor substrate, columnar electrodes having a height of 30 to 150 μm and electrically connected to the connection pads, and a sealing material formed between the columnar electrodes and having openings which expose upper surfaces of the columnar electrodes;
forming adhesive coatings containing an imidazole-based compound on the upper surfaces of the columnar electrodes; and
forming solder balls onto upper surfaces of the adhesive coatings.

7. The manufacturing method according to claim 6, wherein the adhesive coatings are formed by immersing the semiconductor substrate into an imidazole-based compound solution, after forming adhesive coatings on the upper surfaces of the columnar electrodes.

8. A semiconductor device manufacturing method comprising:
providing a semiconductor substrate having a plurality of connection pads on one surface thereof;
forming, on the one surface side of the semiconductor substrate, columnar electrodes made of a copper-based metal and electrically connected to the connection pads, and a sealing material filled between the columnar electrodes and having openings which expose upper surfaces of the columnar electrodes;
forming adhesive coatings containing an imidazole-based compound on the upper surfaces of the columnar electrodes; and
depositing solder balls onto upper surfaces of the adhesive coatings.

9. The manufacturing method according to claim 8, wherein the adhesive coatings are formed by immersing the semiconductor substrate into an imidazole-based compound solution.
